(19) United States
(12) Patent Application Publication
(10) Pub. No.: US 2025/0246508 A1
(43) Pub. Date: Jul. 31, 2025

(54) SEMICONDUCTOR PACKAGE WITH EMBEDDED SKELETAL HEAT TRANSFER STRUCTURE

(71) Applicant: Micron Technology, Inc., Boise, ID (US)

(72) Inventors: Yun Ying CHEN, Taichung (TW); Chong Leong GAN, Taichung (TW); Min Hua CHUNG, Taichung (TW); Lu Fu LIN, Taichung (TW)

(21) Appl. No.: 19/015,056

(22) Filed: Jan. 9, 2025

Related U.S. Application Data
(60) Provisional application No. 63/626,765, filed on Jan. 30, 2024.

(51) Int. Cl. H01L 23/373; H01L 21/48; H01L 21/56

(52) U.S. Cl. CPC H01L 23/3733; H01L 21/4882; H01L 21/56; H01L 23/3737

(57) ABSTRACT

Implementations described herein relate to various semiconductor device assemblies. In some implementations, a semiconductor device assembly includes a semiconductor die, a skeletal heat transfer structure over the semiconductor die; and a casing over the skeletal heat transfer structure that is over the semiconductor die. The skeletal heat transfer structure provides multiple thermal conduction pathways to satisfy a thermal performance threshold of the semiconductor device assembly.

### CROSS-REFERENCE TO RELATED APPLICATION

This patent application claims priority to U.S. Provisional Patent Application No. 63/626,765, filed on Jan. 30, 2024, entitled “SEMICONDUCTOR PACKAGE WITH EMBEDDED SKELETAL HEAT TRANSFER STRUCTURE,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to a semiconductor package with a thermally-conductive structure.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIGS. 1A and 1B are diagrams of example implementations of an apparatus including an embedded skeletal heat transfer structure described herein.

FIG. 2 is a diagram of an example memory device that may be manufactured using techniques described herein.

FIG. 3 is a flowchart of an example method of forming an integrated assembly or memory device having a skeletal heat transfer structure described herein.

FIG. 4 is a flowchart of an example method of forming a skeletal heat transfer structure described herein.

FIG. 5 is a flowchart of an example method of forming a mold compound including thermally-conductive particulates described herein.

FIG. 6 is a flowchart of an example method of forming an integrated assembly or memory device having a skeletal heat transfer structure described herein.

FIG. 7 describes an example series of semiconductor manufacturing operations that may be performed to form a skeletal heat transfer structure described herein.

FIG. 8 describes an example series of semiconductor manufacturing operations that may be performed to form thermally-conductive particulates described herein.

FIG. 9 describes an example series of semiconductor manufacturing operations that may be performed to form an apparatus including a skeletal heat transfer structure described herein.

FIG. 10 describes an example series of semiconductor manufacturing operations that may be performed to form an apparatus including a skeletal heat transfer structure described herein.

### DETAILED DESCRIPTION

A semiconductor package may include a memory device (e.g., a semiconductor die, an integrated circuit, or a “chip”) on a substrate that is configured to store data in memory cells. In some implementations, the semiconductor package includes volatile memory that requires power to maintain stored data and that loses stored data after the semiconductor package is powered off, such as one or more latches and/or random-access memory (RAM), such as dynamic RAM (DRAM) and/or static RAM (SRAM).

In some implementations, the semiconductor package is a multi-chip package (MCP) that includes multiple memory devices. Additionally, or alternatively, the semiconductor package may include a hard drive, a solid-state drive (SSD), a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

In a case where the semiconductor package includes a DRAM device, environmental factors such as temperature and/or voltage may influence a rate of charge leakage from storage cells of the DRAM device which, in turn, can adversely affect a refresh performance of the DRAM device (e.g., increase a frequency at which the storage cells are refreshed with charges corresponding to data stored within the storage cells). Increasing memory densities, increased layer counts that may be included in the substrate of the semiconductor package, and the inclusion of additional devices in the semiconductor package (e.g., logic devices) may further exacerbate the adverse refresh performance.

In some instances, a casing of the semiconductor package surrounds the memory device. The casing (e.g., an epoxy mold compound (EMC)) may have a low thermal conductivity that inhibits heat transfer from the memory device for dissipation to an external environment. In such instances, a heat transfer performance of the semiconductor package may be insufficient for maintaining a junction temperature of the DRAM device at or below a threshold that maintains the refresh performance of the DRAM device.

Some implementations described herein include a semiconductor package including a skeletal heat transfer structure that is embedded in a casing of the semiconductor die package. The skeletal heat transfer structure, located between an integrated circuit (e.g., a semiconductor die) and a surface of the casing, may provide multiple thermal conduction pathways between the integrated circuit and the surface of the casing to transfer heat from the integrated circuit to an environment surrounding the semiconductor die package. The skeletal heat transfer structure may be formed using three-dimensional (3D) printing techniques to print the skeletal heat transfer structure from a material having higher thermal conductivity than an epoxy mold compound included in the casing.

In this way, the thermal control network maintains a junction temperature of the DRAM device at or below a threshold temperature that adversely affects a refresh performance of the DRAM device. By maintaining the refresh performance of the DRAM device, the semiconductor package realizes improved performance benefits that may include improved data retention, improved stability, lower power consumption, and/or lower heat generation, among other examples.

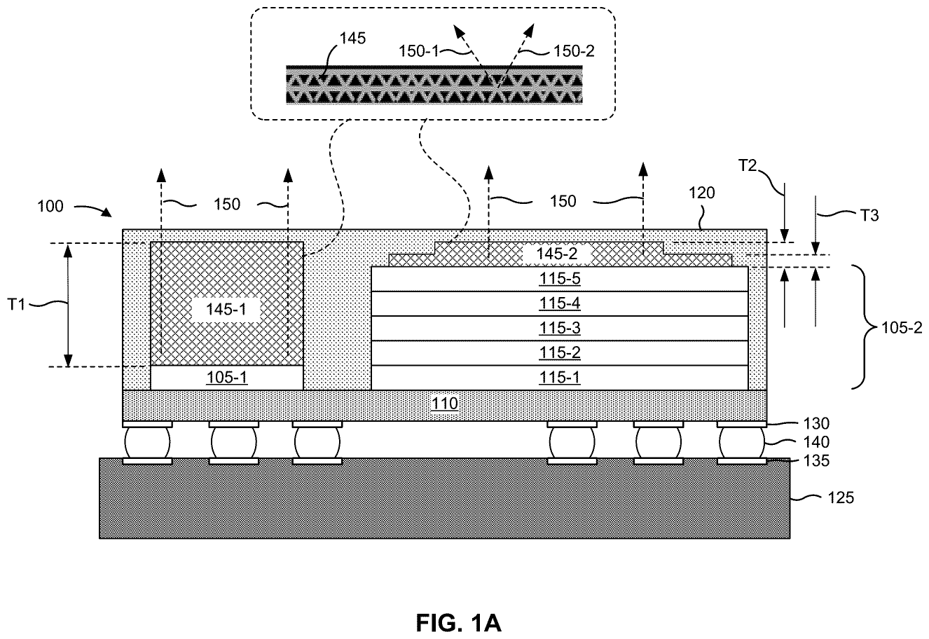

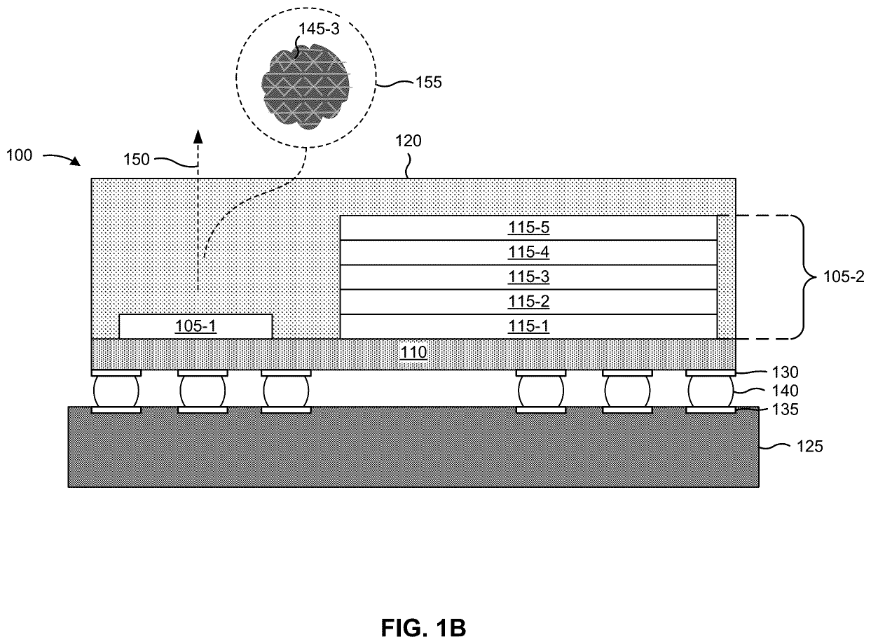

FIGS. 1A and 1B are diagrams of example implementations of an apparatus 100 including an embedded skeletal heat transfer structure described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a graphics double data rate (GDDR) memory device, a high-bandwidth memory (HBM) memory device, a lower power dynamic RAM (LPDRAM) memory device, a static RAM (SRAM) device, a solid state drive (SSD), a microchip, and/or a system on a chip (SoC) device, among other examples. Additionally, or alternatively, the apparatus may include a non-memory device such as a graphics processing unit (GPU) device or a central processing unit (CPU) device, among other examples. In some cases, the apparatus 100 may be referred to as a semiconductor package, an assembly, a semiconductor device assembly, or an integrated assembly.

As shown in the implementation of FIG. 1A, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1A, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1A shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

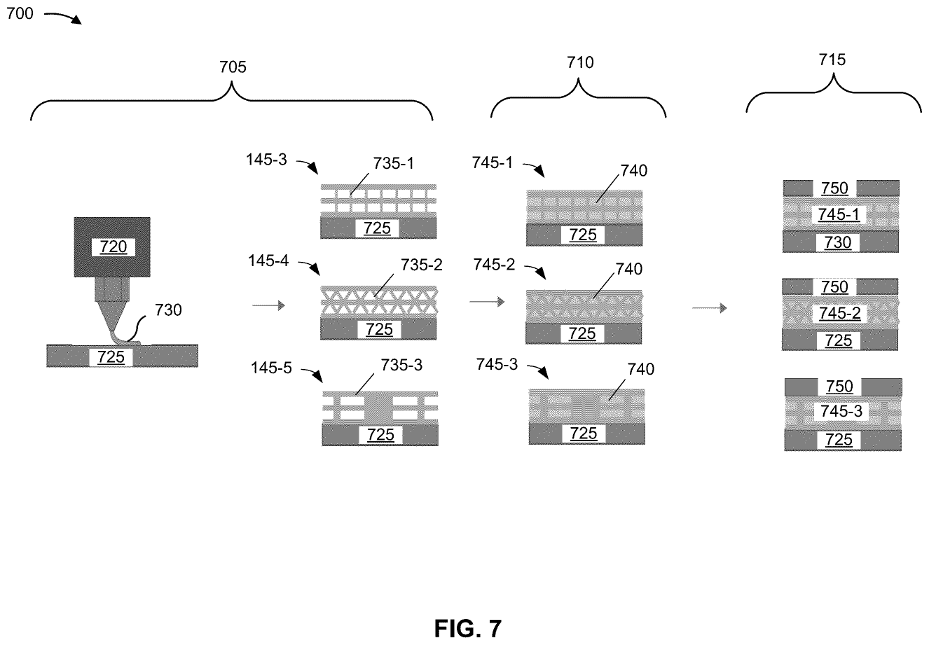

As further shown in FIG. 1A, the apparatus 100 may include a skeletal heat transfer structure 145. As described in greater detail in connection with FIG. 7 and elsewhere herein, the skeletal heat transfer structure 145 may be formed using a sequential layering technique (e.g., a 3D printing technique).

The skeletal heat transfer structure 145 (e.g., a mesh or web-like structure) may be located within the casing 120 and use thermal conduction mechanics to conduct heat 150 (e.g., heat in Watts (W)) generated within the apparatus 100 to an outer surface of the casing 120 for dissipation. Furthermore, and as shown by the example thermal conduction pathways for heat 150-1 and 150-2, the skeletal heat transfer structure 145 may provide multiple thermal conduction pathways between energy sources within the apparatus (e.g., the integrated circuits 105 and/or the dies 115) and the outer surface of the casing 120.

Different implementations of the skeletal heat transfer structure 145 may include different profiles. For example, and as shown in FIG. 1A, a profile of the skeletal heat transfer structure 145-1 (e.g., a skeletal heat transfer structure that is disposed laterally across the integrated circuit 105-1 and has a single segment and a uniform profile) includes a thickness T1 that is approximately consistent (e.g., approximately consistent within reasonable tolerances of manufacturing and measurement). In contrast, the skeletal heat transfer structure 145-2 (e.g., a skeletal heat transfer structure that is disposed laterally across the integrated circuit 105-2 and has at least two segments and a non-uniform profile) includes the thickness T2 and the thickness T3, where the thickness T2 is greater than the thickness T3 (e.g., the at least two segments have different thicknesses). In some implementations, a profile and/or location of the skeletal heat transfer structure 145 is determined and/or selected based on “hot spots” within the apparatus 100.

In some implementations, the skeletal heat transfer structure 145 spans an entire width of the integrated circuits 105 and/or the dies 115. Additionally, or alternatively and in some implementations, the skeletal heat transfer structure 145 spans a partial width of the integrated circuits 105 and/or the dies 115.

The skeletal heat transfer structure 145 may include a first material having a first thermal conductivity (e.g., in Watts per meter Kelvin (W/m. K)) and the casing 120 may include a second material having a second thermal conductivity, where the second thermal conductivity is less than the first thermal conductivity. Examples of the first material that may be included in the skeletal heat transfer structure 145 include silica-coated graphene, silica-coated carbon nanotubes, and/or silica-coated self-aligned nanoparticles (e.g., nanoparticles including a metal material such as silver (Ag) or copper (Cu)), among other examples. Examples of the second material that may be included in the casing 120 include an epoxy mold compound (EMC), among other examples.

As shown in FIG. 1B, and similar to the implementation described in connection with FIG. 1A, another example implementation of the apparatus 100 includes the integrated circuits 105, the substrate 110, the dies 115, the casing 120, the circuit board 125, the electrical contacts 130, the electrical contacts 135, and the solder balls 140. However, and in contrast to including the skeletal heat transfer structure 145-1 and/or the skeletal heat transfer structure 145-2 described in connection with FIG. 1A, the apparatus 100 includes thermally-conductive particulates 155 that are embedded in a material of the casing 120 (e.g., embedded in an epoxy mold compound).

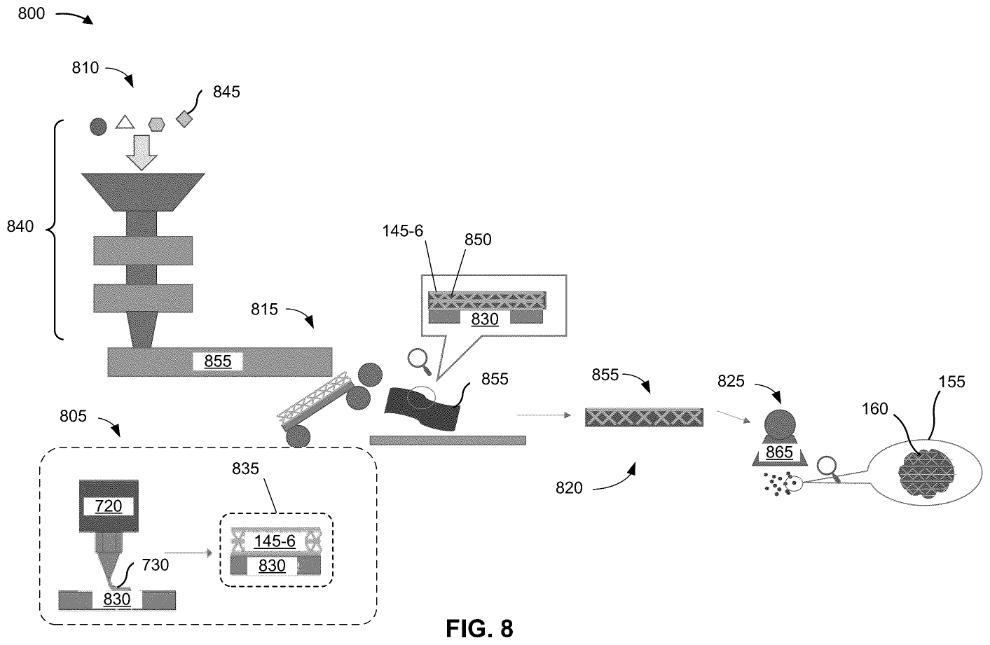

Each of the thermally-conductive particulates 155 includes at least one micro-skeletal heat transfer structure 160. As described in greater detail in connection with FIG. 8, the micro-skeletal heat transfer structure 160 may be formed using a sequential layering technique (e.g., a 3D printing technique).

As described in connection with FIGS. 1A and 1B, and in some implementations, a semiconductor device assembly (e.g., the apparatus 100) includes a semiconductor die (e.g., at least one of the dies 115), a skeletal heat transfer structure (e.g., the skeletal heat transfer structure 145) over the semiconductor die, and a casing (e.g., the casing 120) over the skeletal heat transfer structure that is over the semiconductor die.

Additionally, or alternatively and in some implementations, a semiconductor device assembly (e.g., the apparatus 100) includes a semiconductor die (e.g., at least one of the dies 115) and a casing (e.g., the casing 120) that includes a mold compound having embedded, thermally-conductive particulates (e.g., the thermally-conductive particulates 155). In some implementations, the thermally-conductive particulates include micro-skeletal heat transfer structures (e.g., each of the thermally-conductive particulates includes one or more of the micro-skeletal heat transfer structures 160).

As indicated above, FIGS. 1A and 1B are provided as examples. Other examples may differ from what is described with regard to FIGS. 1A and 1B.

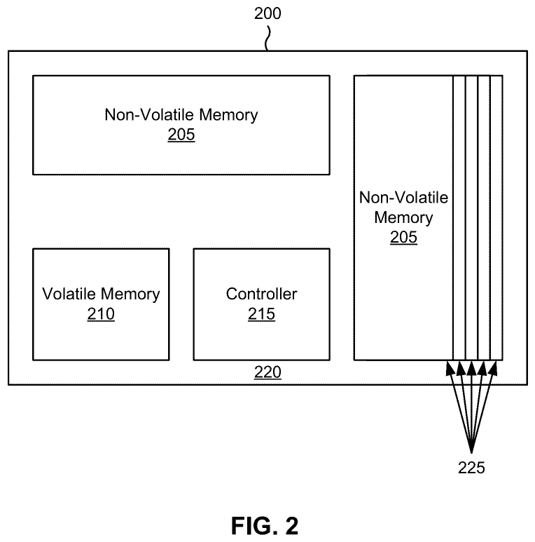

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (cMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

One or more apparatuses, assemblies, and/or devices described in connection with FIGS. 1A, 1B, and or 2 may include a thermal control network having one or more skeletal heat transfer structures (e.g., one or more of the skeletal heat transfer structure 145 and/or the micro-skeletal heat transfer structure 160). The thermal control network may conduct and/or transfer heat (e.g., the heat 150) to maintain a junction temperature of one or more integrated circuit devices (e.g., a junction temperature of one or more of the dies 115, including the non-volatile memory 205, the volatile memory 210, and/or the controller 215) at or below a temperature that adversely affects a performance of the integrated circuit devices. By maintaining the junction temperature at or below such a temperature, the apparatuses, assemblies, and/or devices may satisfy one or more performance thresholds related to data retention, stability, power consumption, and/or heat generation, among other examples.

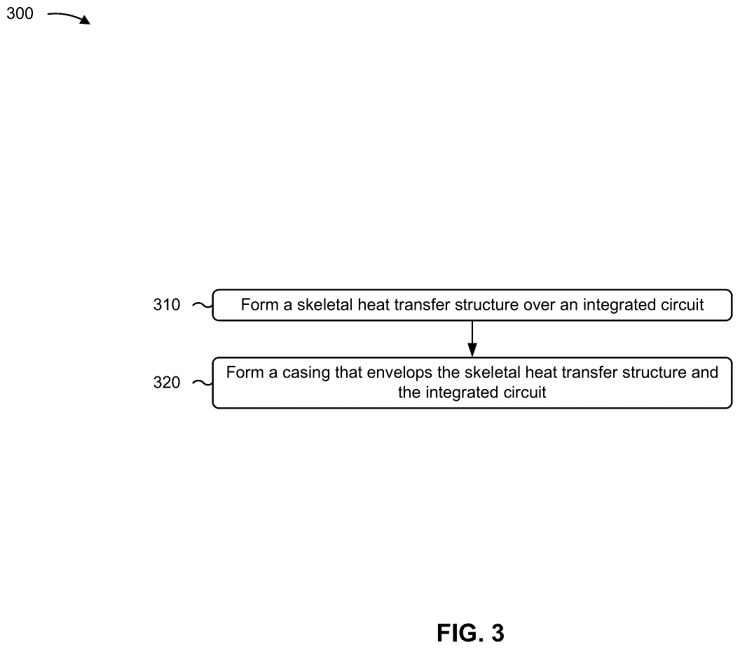

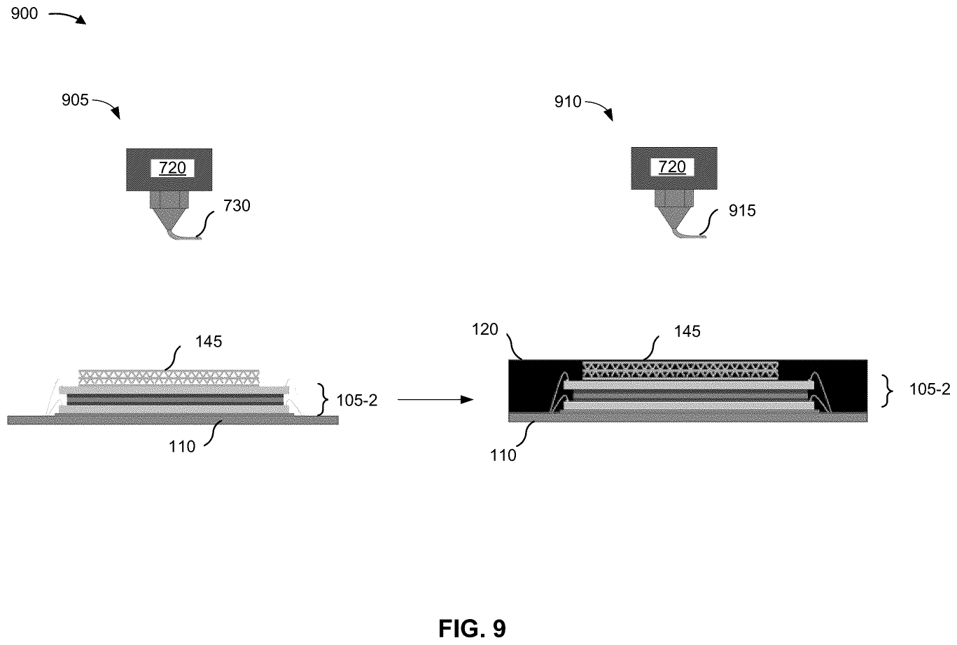

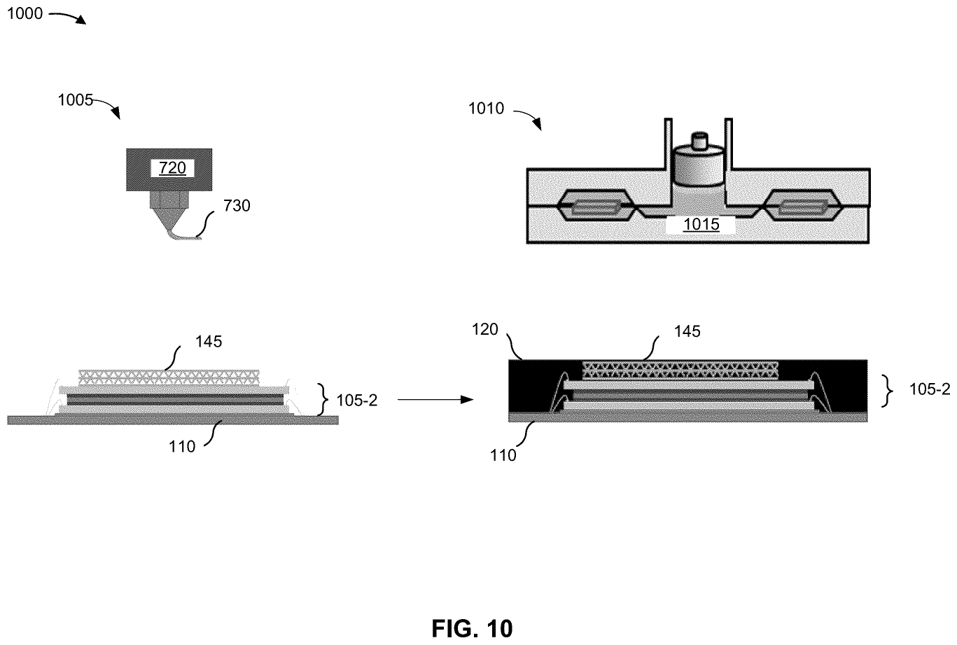

FIG. 3 is a flowchart of an example method 300 of forming an integrated assembly or memory device having a skeletal heat transfer structure described herein (e.g., the skeletal heat transfer structure 145). In some implementations, and as described in greater detail in connection with FIGS. 9 and 10, one or more process blocks of FIG. 3 may be performed by various semiconductor manufacturing equipment.

As shown in FIG. 3, the method 300 may include forming a skeletal heat transfer structure (e.g., the skeletal heat transfer structure 145) over an integrated circuit (e.g., the integrated circuit 105) (block 310). As further shown in FIG. 3, the method 300 may include forming a casing (e.g., the casing 120) that envelops the skeletal heat transfer structure and the integrated circuit (block 320).

The method 300 may include additional aspects, such as any single aspect or any combination of aspects described below and/or in connection with one or more other methods described elsewhere herein.

In a first aspect, forming the skeletal heat transfer structure includes using a sequential layering operation that prints the skeletal heat transfer structure over the integrated circuit.

In a second aspect, alone or in combination with the first aspect, forming the skeletal heat transfer structure includes using a pick-and-place operation that places the skeletal heat transfer structure over the integrated circuit.

In a third aspect, alone or in combination with one or more of the first and second aspects, forming the casing includes using a sequential layering operation to form a matrix of a resin that envelops the skeletal heat transfer structure and the integrated circuit.

In a fourth aspect, alone or in combination with one or more of the first through third aspects, forming the casing includes using a molding operation to form a matrix of a resin that envelops the skeletal heat transfer structure and the integrated circuit.

In a fifth aspect, alone or in combination with one or more of the first through fourth aspects, using the molding operation includes using a transfer molding operation, or using a compression molding operation.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the skeletal heat transfer structure (e.g., the skeletal heat transfer structure 145 and/or the micro-skeletal heat transfer structure 160), an integrated assembly that includes the skeletal heat transfer structure, any part described herein of the skeletal heat transfer structure, and/or any part described herein of an integrated assembly that includes the skeletal heat transfer structure. For example, the method 300 may include forming one or more of the apparatuses, assemblies, and/or devices described in connection with FIGS. 1A, 1B, and/or 2 (e.g., one or more of the apparatus 100, the memory device 200, the non-volatile memory 205, the volatile memory 210, and/or controller 215 that include the skeletal heat transfer structure 145 and/or the micro-skeletal heat transfer structure 160). Additionally, or alternatively, the method 300 may include forming one or more apparatuses, assemblies, and/or devices including a non-memory device or a non-storage device, such as a GPU device or a CPU device, among other examples.

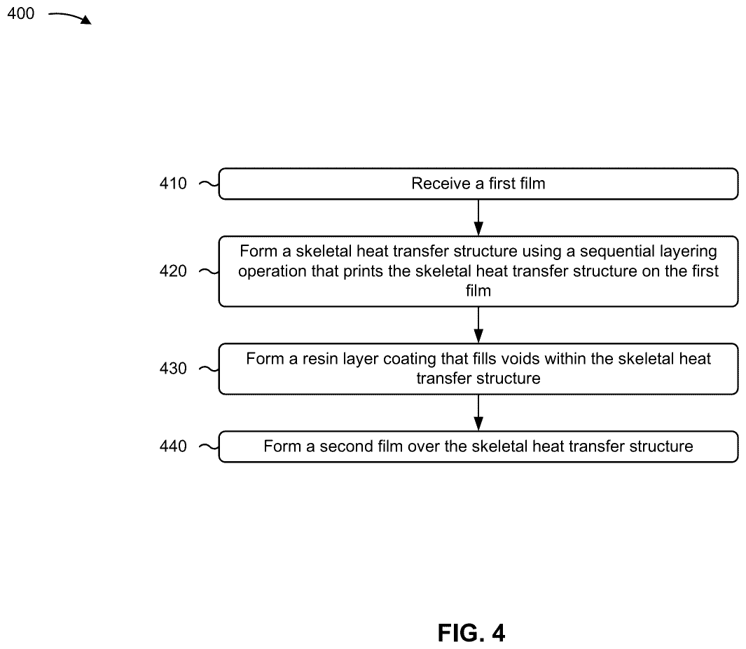

FIG. 4 is a flowchart of an example method 400 of forming a skeletal heat transfer structure described herein (e.g., the skeletal heat transfer structure 145). In some implementations, and as described in greater detail in connection with FIG. 7, one or more process blocks of FIG. 4 may be performed by various semiconductor manufacturing equipment.

As shown in FIG. 4, the method 400 may include receiving a first film (block 410). As further shown in FIG. 4, the method 400 may include forming a skeletal heat transfer structure (e.g., the skeletal heat transfer structure 145) using a sequential layering operation that prints the skeletal heat transfer structure on the first film (block 420). As further shown in FIG. 4, the method 400 may include forming a resin layer coating that fills voids within the skeletal heat transfer structure (block 430). As further shown in FIG. 4, the method 400 may include forming a second film over the skeletal heat transfer structure (block 440).

The method 400 may include additional aspects, such as any single aspect or any combination of aspects described below and/or in connection with one or more other methods described elsewhere herein.

In a first aspect, receiving the first film includes receiving a polyethylene terephthalate film.

In a second aspect, alone or in combination with the first aspect, forming the resin layer coating includes forming a layer of a thermosetting resin material that includes a solvent, and curing the layer of the thermosetting resin material to evaporate the solvent.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the skeletal heat transfer structure (e.g., the skeletal heat transfer structure 145 and/or the micro-skeletal heat transfer structure 160), an integrated assembly that includes the skeletal heat transfer structure, any part described herein of the skeletal heat transfer structure, and/or any part described herein of an integrated assembly that includes the skeletal heat transfer structure. For example, the method 400 may include forming one or more of the apparatuses, assemblies, and/or devices described in connection with FIGS. 1A, 1B, and or 2 (e.g., one or more of the apparatus 100, the memory device 200, the non-volatile memory 205, the volatile memory 210, and/or controller 215 that include the skeletal heat transfer structure 145 and/or the micro-skeletal heat transfer structure 160). Additionally, or alternatively, the method 400 may include forming one or more apparatuses, assemblies, and/or devices including a non-memory device or a non-storage device, such as a GPU device or a CPU device, among other examples.

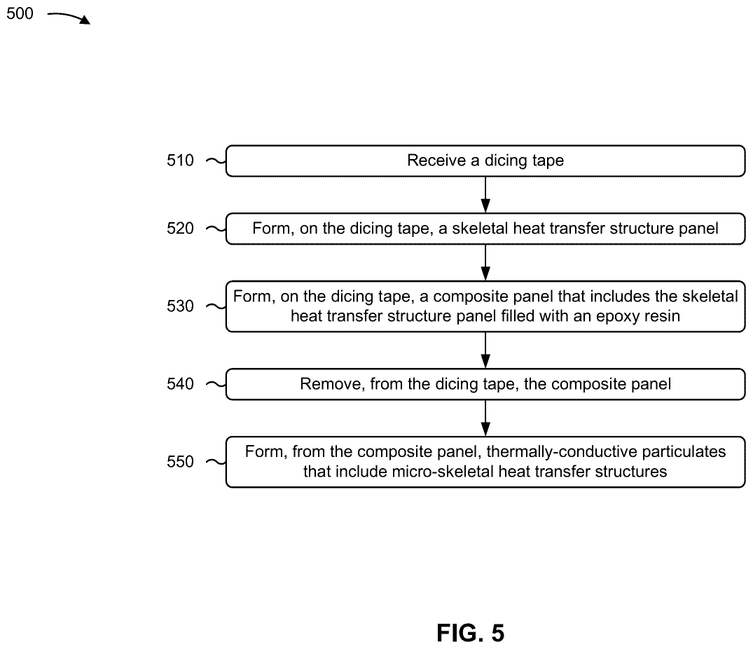

FIG. 5 is a flowchart of an example method 500 of forming a mold compound including thermally-conductive particulates described herein (e.g., the thermally-conductive particulates 155 including the micro-skeletal heat transfer structure 160). In some implementations, and as described in greater detail in connection with FIG. 8, one or more process blocks of FIG. 5 may be performed by various semiconductor manufacturing equipment.

As shown in FIG. 5, the method 500 may include receiving a dicing tape (block 510). As further shown in FIG. 5, the method 500 may include forming, on the dicing tape, a skeletal heat transfer structure panel (block 520). As further shown in FIG. 5, the method 500 may include forming, on the dicing tape, a composite panel that includes the skeletal heat transfer structure panel filled with an epoxy resin (block 530). As further shown in FIG. 5, the method 500 may include removing, from the dicing tape, the composite panel (block 540). As further shown in FIG. 5, the method 500 may include forming, from the composite panel, thermally-conductive particulates (e.g., the thermally-conductive particulates 155) that include micro-skeletal heat transfer structures (e.g., the micro-skeletal heat transfer structure 160) (block 550).

The method 500 may include additional aspects, such as any single aspect or any combination of aspects described below and/or in connection with one or more other methods described elsewhere herein.

In a first aspect, forming the skeletal heat transfer structure panel includes forming the skeletal heat transfer structure panel using a sequential layering operation.

In a second aspect, alone or in combination with the first aspect, forming the composite panel includes forming the composite panel using a kneading operation that fills voids in the skeletal heat transfer structure panel with the epoxy resin.

In a third aspect, alone or in combination with one or more of the first and second aspects, removing the composite panel includes removing the composite panel from the dicing tape using an ultraviolet release operation.

In a fourth aspect, alone or in combination with one or more of the first through third aspects, removing the composite panel includes removing the composite panel from the dicing tape using a thermal release operation.

In a fifth aspect, alone or in combination with one or more of the first through fourth aspects, forming the thermally-conductive particulates includes forming the thermally-conductive particulates using a crusher operation that crushes the composite panel.

In a sixth aspect, alone or in combination with one or more of the first through fifth aspects, the method 500 includes forming a tablet of an epoxy mold compound that includes the thermally-conductive particulates.

In a seventh aspect, alone or in combination with one or more of the first through sixth aspects, the method 500 includes forming a sieve of an epoxy mold compound that includes the thermally-conductive particulates.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the skeletal heat transfer structure (e.g., the skeletal heat transfer structure 145 and/or the micro-skeletal heat transfer structure 160), an integrated assembly that includes the skeletal heat transfer structure, any part described herein of the skeletal heat transfer structure, and/or any part described herein of an integrated assembly that includes the skeletal heat transfer structure. For example, the method 500 may include forming one or more of the apparatuses, assemblies, and/or devices described in connection with FIGS. 1A, 1B, and/or 2 (e.g., one or more of the apparatus 100, the memory device 200, the non-volatile memory 205, the volatile memory 210, and/or controller 215 that include the skeletal heat transfer structure 145 and/or the micro-skeletal heat transfer structure 160). Additionally, or alternatively, the method 500 may include forming one or more apparatuses, assemblies, and/or devices including a non-memory device or a non-storage device, such as a GPU device or a CPU device, among other examples.

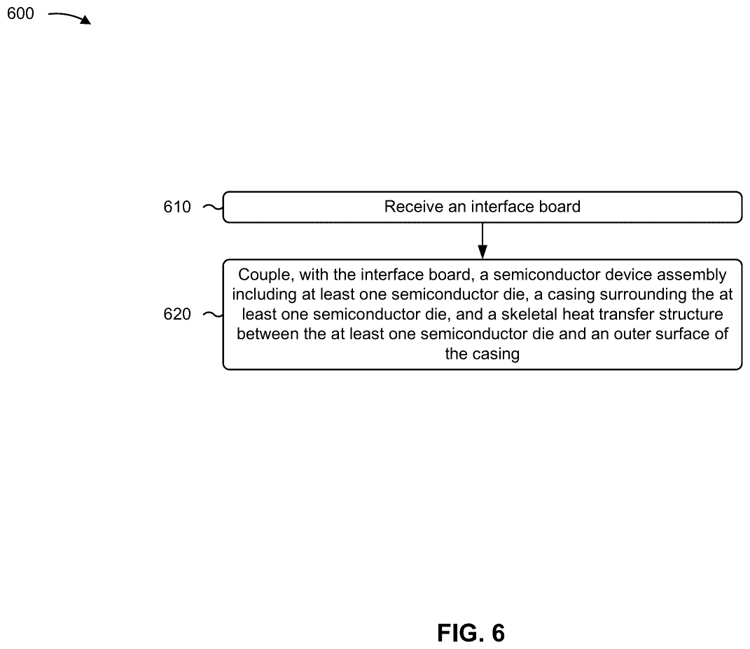

FIG. 6 is a flowchart of an example method 600 of forming an integrated assembly or memory device having a skeletal heat transfer structure (e.g., the skeletal heat transfer structure 145 and/or the micro-skeletal heat transfer structure 160). In some implementations, one or more process blocks of FIG. 6 may be performed by various semiconductor manufacturing equipment.

As shown in FIG. 6, the method 600 may include receiving an interface board (block 610). As further shown in FIG. 6, the method 600 may include coupling, with the interface board, a semiconductor device assembly (e.g., the apparatus 100 or the memory device 200) including at least one semiconductor die (e.g., at least one of the dies 115), a casing (e.g., the casing 120) surrounding the at least one semiconductor die, and a skeletal heat transfer structure (e.g., the skeletal heat transfer structure 145 and/or the micro-skeletal heat transfer structure 160) between the at least one semiconductor die and an outer surface of the casing (block 620).

The method 600 may include additional aspects, such as any single aspect or any combination of aspects described below and/or in connection with one or more other methods described elsewhere herein.

In a first aspect, the method 600 includes forming the skeletal heat transfer structure over the at least one semiconductor die using a three-dimensional printing operation.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the skeletal heat transfer structure (e.g., the skeletal heat transfer structure 145 and/or the micro-skeletal heat transfer structure 160), an integrated assembly that includes the skeletal heat transfer structure, any part described herein of the skeletal heat transfer structure, and/or any part described herein of an integrated assembly that includes the skeletal heat transfer structure. For example, the method 600 may include forming one or more of the apparatuses, assemblies, and/or devices described in connection with FIGS. 1A, 1B, and/or 2 (e.g., one or more of the apparatus 100, the memory device 200, the non-volatile memory 205, the volatile memory 210, and/or controller 215 that include the skeletal heat transfer structure 145 and/or the micro-skeletal heat transfer structure 160). Additionally, or alternatively, the method 600 may include forming one or more apparatuses, assemblies, and/or devices including a non-memory device or a non-storage device, such as a GPU device or a CPU device, among other examples.

FIG. 7 describes an example series of semiconductor manufacturing operations 700 that may be performed to form a skeletal heat transfer structure (e.g., the skeletal heat transfer structure 145) described herein. One or more of the series of semiconductor manufacturing operations 700 may correspond to one or more of the blocks described in connection with the method 400 of FIG. 4, among other examples.

As shown in FIG. 7, the series of semiconductor manufacturing operations 700 includes a sequential layering operation 705 (e.g., a 3D printing operation). The series of semiconductor manufacturing operations 700 further includes a coating operation 710 and a laminating operation 715.

As part of the sequential layering operation 705, a printing tool 720 (e.g., a 3D printer, an extruder, or a print head) may be used to receive a film 725. The film 725 (e.g., a first film) may be a polyethylene terephthalate (PET) film, among other examples. The printing tool 720 may use one of several additive manufacturing techniques (e.g., a fused filament fabrication (FFF) technique, a fused deposition modeling (FDM) technique, a stercolithography (SLA) technique, or a digital light processing technique) to sequentially deposit layers and/or three-dimensional patterns of a thermally-conductive material 730 (e.g., a material including silica-coated graphene, silica-coated carbon nanotubes, and/or silica-coated self-aligned nanoparticles).

As shown in FIG. 7, the sequential layering operation 705 may form different patterns and/or combinations of substructures from the thermally-conductive material 730. For example, the sequential layering operation 705 may form the skeletal heat transfer structure 145-3 having a pattern that includes vertically-oriented substructures 735-1. Additionally, or alternatively, the sequential layering operation 705 may form the skeletal heat transfer structure 145-4 having a pattern that includes crosshatched substructures 735-2. Additionally, or alternatively, the sequential layering operation 705 may form the skeletal heat transfer structure 145-5 having a pattern that includes horizontally-oriented substructures 735-3.

As shown in FIG. 7, and as part of the coating operation 710, a coating tool may use one of several application techniques (e.g., a roller technique, a spray technique, a dip technique, a dispense/flow technique, or a laminating technique) to form a resin layer coating 740 that combines with (e.g., fills voids within) the skeletal heat transfer structure 145 to form a composite structure 745. For example, and as shown in FIG. 7, the skeletal heat transfer structure 145-3 combines with the resin layer coating 740 to form the composite structure 745-1, the skeletal heat transfer structure 145-5 combines with the resin layer coating 740 to form the composite structure 745-2, and the skeletal heat transfer structure 145-6 combines with the resin layer coating 740 to form the composite structure 745-3.

In some implementations, the resin layer coating 740 includes a thermosetting resin material that includes a solvent. In such a case, the coating operation 710 may include curing the resin layer coating 740 at an elevated temperature to evaporate the solvent.

As shown in FIG. 7, and as part of the laminating operation 715, a laminating tool may form (e.g., attach) a film 750 over the composite structure 745. The film 750 (e.g., a second film) may be a cover film that includes a transparent and/or an adhesive tape to protect the composite structure 745 from damage or contamination during transport of the composite structure 745 to another series of semiconductor manufacturing operations that may further integrate the skeletal heat transfer structure 145 into a non-memory device (e.g., a GPU or a CPU), a memory device, an apparatus, assembly, and/or another device as described in connection with FIGS. 1A, 1B, and or 2.

As indicated above, FIG. 7 is provided as an example. Other examples may differ from what is described with regard to FIG. 7.

FIG. 8 describes an example series of semiconductor manufacturing operations 800 that may be performed to form thermally-conductive particulates (e.g., the thermally-conductive particulates 155) described herein. One or more of the series of semiconductor manufacturing operations 800 may correspond to one or more of the blocks described in connection with the method 500 of FIG. 5, among other examples.

As shown in FIG. 8, the series of semiconductor manufacturing operations 800 includes a sequential layering operation 805 (e.g., a 3D printing operation). The series of semiconductor manufacturing operations 800 further includes a mixing operation 810, a kneading operation 815, a release operation 820, and a crushing operation 825.

As part of the sequential layering operation 805, the printing tool 720 (e.g., a 3D printer, an extruder, or a print head) may receive a film 830. In contrast to the film 725 described in connection with FIG. 7 (e.g., a PET film), the film 830 may be a dicing tape that includes an adhesive that is sensitive to ultraviolet (UV) light and/or an elevated temperature. As part of the sequential layering operation 805, the printing tool 720 may use one of several additive manufacturing techniques (e.g., an FFF technique, an FDM technique, an SLA technique, or a digital light processing technique) to sequentially deposit layers and/or 3D patterns of the thermally-conductive material 730 (e.g., a material including silica-coated graphene, silica-coated carbon nanotubes, and/or silica-coated self-aligned nanoparticles). The sequential layering operation 805 may form a skeletal heat transfer structure panel 835 that includes the skeletal heat transfer structure 145-6 on the film 830.

As part of the mixing operation 810, a mixer tool 840 may receive a combination of raw materials 845 that may be used as part of forming an epoxy resin 850. The combination of raw materials 845 may include a resin material and/or a catalyst material, among other examples.

As part of the kneading operation 815, a kneading tool 855 may use a kneading operation to fills voids in the skeletal heat transfer structure panel 835 (e.g., voids within the skeletal heat transfer structure 145-6) with the epoxy resin 850. Filling the voids in the skeletal heat transfer structure panel 835 may form a composite panel 855 on the film 830.

As part of the release operation 820, a release tool may use one of several techniques to separate the composite panel 855 from the film 830. Such techniques may include using a UV release technique or a thermal release technique, among other examples.

As part of the crushing operation 825, a crushing tool 865 (a combination of a hopper, cutting blades, mill fixtures, and/or motors, among other examples) may crush the composite panel 855 to form the thermally-conductive particulates 155, where each of the thermally-conductive particulates 155 includes the micro-skeletal heat transfer structure 160.

In some implementations, the series of semiconductor manufacturing operations 800 further includes forming a table of an epoxy mold compound that includes the thermally-conductive particulates 155. Alternatively, and in some implementations, the series of semiconductor manufacturing operations 800 further includes forming a sieve of an epoxy mold compound that includes the thermally-conductive particulates 155.

As indicated above, FIG. 8 is provided as an example. Other examples may differ from what is described with regard to FIG. 8.

FIG. 9 describes an example series of semiconductor manufacturing operations 900 that may be performed to form an apparatus including a skeletal heat transfer structure (e.g., the skeletal heat transfer structure 145) described herein. One or more of the series of semiconductor manufacturing operations 900 may correspond to one or more of the blocks described in connection with the method 300 of FIG. 3, among other examples.

As shown in FIG. 9, the series of semiconductor manufacturing operations 900 includes a sequential layering operation 905 (e.g., a 3D printing operation). The series of semiconductor manufacturing operations 900 further includes a molding operation 910.

As part of the sequential layering operation 905, the printing tool 720 may usc one of several additive manufacturing techniques (e.g., an FFF technique, an FDM technique, an SLA technique, or a digital light processing technique) to sequentially deposit layers and/or three-dimensional patterns of the thermally-conductive material 730 (e.g., a material including silica-coated graphene, silica-coated carbon nanotubes, and/or silica-coated self-aligned nanoparticles). The sequential layering operation 905 may form a skeletal heat transfer structure 145 over, on, and/or across the integrated circuit 105-2.

Alternatively, a pick-and-place tool may be used to form the skeletal heat transfer structure 145 over, on, and/or across the integrated circuit 105-2, where the pick-and-place tool receives the skeletal heat transfer structure 145 in a pre-formed state (e.g., the skeletal heat transfer structure 145 is pre-formed using one or more techniques described in connection with FIG. 7).

As part of the molding operation 910, the printing tool 720 may use one of several additive manufacturing techniques (e.g., an FFF technique, an FDM modeling technique, an SLA technique, or a digital light processing technique) to deposit a resin material 915 and form a matrix of the resin material that envelops the skeletal heat transfer structure 145 and the integrated circuit 105-2 (e.g., forms the casing 120).

As indicated above, FIG. 9 is provided as an example. Other examples may differ from what is described with regard to FIG. 9.

FIG. 10 describes an example series of semiconductor manufacturing operations 1000 that may be performed to form an apparatus including a skeletal heat transfer structure (e.g., the skeletal heat transfer structure 145) described herein. One or more of the series of semiconductor manufacturing operations 1000 may correspond to one or more of the blocks described in connection with the method 300 of FIG. 3, among other examples.

As shown in FIG. 10, the series of semiconductor manufacturing operations 1000 includes a sequential layering operation 1005 (e.g., a 3D printing operation). The series of semiconductor manufacturing operations 900 further includes a molding operation 1010.

As part of the sequential layering operation 1005, the printing tool 720 may use one of several additive manufacturing techniques (e.g., an FFF technique, an FDM technique, an SLA technique, or a digital light processing technique) to sequentially deposit layers and/or three-dimensional patterns of the thermally-conductive material 730 (e.g., a material including silica-coated graphene, silica-coated carbon nanotubes, and/or silica-coated self-aligned nanoparticles). The sequential layering operation 1005 may form a skeletal heat transfer structure 145 over, on, and/or across the integrated circuit 105-2.

Alternatively, a pick-and-place tool may be used to form the skeletal heat transfer structure 145 over, on, and/or across the integrated circuit 105-2, where the pick-and-place tool receives the skeletal heat transfer structure 145 in a pre-formed state (e.g., the skeletal heat transfer structure 145 is pre-formed using one or more techniques described in connection with FIG. 7).

As part of the molding operation 1010, an encapsulation tool 1015 may use one of several molding techniques (e.g., a transfer molding technique or a compression molding technique) to form a matrix of a resin material that envelops the skeletal heat transfer structure 145 and the integrated circuit 105-2 (e.g., forms the casing 120).

As indicated above, FIG. 10 is provided as an example. Other examples may differ from what is described with regard to FIG. 10.

In some implementations, a semiconductor device assembly includes a semiconductor die; a skeletal heat transfer structure over the semiconductor die; and a casing over the skeletal heat transfer structure that is over the semiconductor die.

In some implementations, a semiconductor device assembly includes a semiconductor die; and a casing that includes a mold compound having embedded, thermally-conductive particulates, wherein the thermally-conductive particulates include micro-skeletal heat transfer structures.

In some implementations, a method includes forming a skeletal heat transfer structure over an integrated circuit; and forming a casing that envelops the skeletal heat transfer structure and the integrated circuit.

In some implementations, a method includes receiving a first film; forming a skeletal heat transfer structure using a sequential layering operation that prints the skeletal heat transfer structure on the first film; forming a resin layer coating that fills voids within the skeletal heat transfer structure; and forming a second film over the skeletal heat transfer structure.

In some implementations, a method includes receiving a dicing tape; forming, on the dicing tape, a skeletal heat transfer structure panel; forming, on the dicing tape, a composite panel that includes the skeletal heat transfer structure panel filled with an epoxy resin; removing, from the dicing tape, the composite panel; and forming, from the composite panel, thermally-conductive particulates that include micro-skeletal heat transfer structures.

In some implementations, a method includes receiving an interface board; and coupling, with the interface board, a semiconductor device assembly including at least one semiconductor die, a casing surrounding the at least one semiconductor die, and a skeletal heat transfer structure between the at least one semiconductor die and an outer surface of the casing.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a semiconductor die;
a skeletal heat transfer structure over the semiconductor die; and
a casing over the skeletal heat transfer structure that is over the semiconductor die.

2. The semiconductor device assembly of claim 1, wherein the skeletal heat transfer structure provides multiple thermal conduction pathways between the semiconductor die and an outer surface of the casing.

3. The semiconductor device assembly of claim 1, wherein the skeletal heat transfer structure comprises a first material having a first thermal conductivity, and wherein the casing comprises:
a second material having a second thermal conductivity that is less than the first thermal conductivity.

4. The semiconductor device assembly of claim 1, wherein the skeletal heat transfer structure is disposed laterally across the semiconductor die and comprises:
a thickness that is approximately consistent.

5. The semiconductor device assembly of claim 1, wherein the skeletal heat transfer structure is disposed laterally across the semiconductor die and comprises:
at least two segments having different thicknesses.

6. The semiconductor device assembly of claim 1, wherein the skeletal heat transfer structure comprises:
a pattern including vertically-oriented substructures.

7. The semiconductor device assembly of claim 1, wherein the skeletal heat transfer structure comprises:
a pattern including crosshatched substructures.

8. The semiconductor device assembly of claim 1, wherein the skeletal heat transfer structure comprises:
a pattern including of horizontally-oriented substructures.

9. The semiconductor device assembly of claim 1, wherein the skeletal heat transfer structure spans an entire width of the semiconductor die.

10. The semiconductor device assembly of claim 1, wherein the skeletal heat transfer structure spans a partial width of the semiconductor die.

11. A semiconductor device assembly, comprising:
a semiconductor die; and
a casing that includes a mold compound having embedded, thermally-conductive particulates,
wherein the thermally-conductive particulates include micro-skeletal heat transfer structures.

12. The semiconductor device assembly of claim 11, wherein the micro-skeletal heat transfer structures comprise:
silica-coated graphene.

13. The semiconductor device assembly of claim 11, wherein the micro-skeletal heat transfer structures comprise:
silica-coated carbon nanotubes.

14. The semiconductor device assembly of claim 11, wherein the micro-skeletal heat transfer structures comprise:
silica-coated self-aligned nanoparticles.

15. The semiconductor device assembly of claim 14, wherein the silica-coated self-aligned nanoparticles comprise:
a metal material.

16. The semiconductor device assembly of claim 15, wherein the metal material comprises:
silver, or
copper.

17. A method, comprising:
forming a skeletal heat transfer structure over an integrated circuit; and
forming a casing that envelops the skeletal heat transfer structure and the integrated circuit.

18. The method of claim 17, wherein forming the skeletal heat transfer structure includes:
using a sequential layering operation that prints the skeletal heat transfer structure over the integrated circuit.

19. The method of claim 17, wherein forming the skeletal heat transfer structure includes:
using a pick-and-place operation that places the skeletal heat transfer structure over the integrated circuit.

20. The method of claim 17, wherein forming the casing includes:
using a sequential layering operation to form a matrix of a resin that envelops the skeletal heat transfer structure and the integrated circuit.

21. The method of claim 17, wherein forming the casing includes:
using a molding operation to form a matrix of a resin that envelops the skeletal heat transfer structure and the integrated circuit.

22. The method of claim 21, wherein using the molding operation includes:
using a transfer molding operation, or
using a compression molding operation.

23. A method, comprising:
receiving a first film;
forming a skeletal heat transfer structure using a sequential layering operation that prints the skeletal heat transfer structure on the first film;
forming a resin layer coating that fills voids within the skeletal heat transfer structure; and
forming a second film over the skeletal heat transfer structure.

24. The method of claim 23, wherein receiving the first film includes:
receiving a polyethylene terephthalate film.

25. The method of claim 23, wherein forming the resin layer coating includes:
forming a layer of a thermosetting resin material that includes a solvent; and
curing the layer of the thermosetting resin material to evaporate the solvent.

26. A method, comprising:
receiving a dicing tape;
forming, on the dicing tape, a skeletal heat transfer structure panel;
forming, on the dicing tape, a composite panel that includes the skeletal heat transfer structure panel filled with an epoxy resin;
removing, from the dicing tape, the composite panel; and
forming, from the composite panel, thermally-conductive particulates that include micro-skeletal heat transfer structures.

27. The method of claim 26, wherein forming the skeletal heat transfer structure panel includes:
forming the skeletal heat transfer structure panel using a sequential layering operation.

28. The method of claim 26, wherein forming the composite panel includes:
forming the composite panel using a kneading operation that fills voids in the skeletal heat transfer structure panel with the epoxy resin.

29. The method of claim 26, wherein removing the composite panel includes:
removing the composite panel from the dicing tape using an ultraviolet release operation.

30. The method of claim 26, wherein removing the composite panel includes:
removing the composite panel from the dicing tape using a thermal release operation.

31. The method of claim 26, wherein forming the thermally-conductive particulates includes:
forming the thermally-conductive particulates using a crusher operation that crushes the composite panel.

32. The method of claim 26, further comprising:
forming a tablet of an epoxy mold compound that includes the thermally-conductive particulates.

33. The method of claim 26, further comprising:
forming a sieve of an epoxy mold compound that includes the thermally-conductive particulates.

34. A method, comprising:
receiving an interface board; and
coupling, with the interface board, a semiconductor device assembly including at least one semiconductor die, a casing surrounding the at least one semiconductor die, and a skeletal heat transfer structure between the at least one semiconductor die and an outer surface of the casing.

35. The method of claim 34, further comprising:
forming the skeletal heat transfer structure over the at least one semiconductor die using a three-dimensional printing operation.
